(19) United States
(12) Patent Application Publication
(10) Pub. No.: US 2008/0111623 A1
(43) Pub. Date: May 15, 2008

(54) INPUT SIGNAL POWER CONTROL

(75) Inventor: Timothy M. Magnusen, Murphy, TX (US)

Correspondence Address: FULBRIGHT & JAWORSKI L.L.P, 2200 ROSS AVENUE, SUITE 2800, DALLAS, TX, 75201-2784, US

(73) Assignee: Microtune (Texas), L.P., Plano, TX (US)

(21) Appl. No.: 11/560,093

(22) Filed: Nov. 15, 2006

(51) Int. Cl. H03F 1/00

(52) U.S. Cl. 330/151

(57) ABSTRACT

A level control circuit is responsive to some parameter of an input signal, e.g., signal level, to selectively bypass around an active circuit (e.g., amplifier stage) rendered unnecessary in view of the detected condition of the input signal, e.g., a signal level satisfying some threshold criteria. In addition to bypassing the active circuit, the control circuit may interrupt power to the circuit. In the case of amplifier stage that may be part of a radio frequency (RF) input stage of a receiver or tuner, upon detecting some threshold input signal level, the amplifier circuit is bypassed, i.e., taken out of the circuit and power to the circuit removed.

### CROSS-REFERENCE TO RELATED APPLICATIONS

The presented application is related to and incorporates by reference herein in their entireties the disclosures of U.S. patent application Ser. No. 11/376,745 filed Mar. 15, 2006 and entitled Broadband Integrated Tuner; U.S. patent application Ser. No. 08/426,080 filed Apr. 21, 1995, now U.S. Pat. No. 5,737,035 and entitled Highly Integrated Television Tuner on a Single Microcircuit; U.S. patent application Ser. No. 08/904,908 filed Aug. 1, 1997, now U.S. Pat. No. 6,177,964 and entitled Broadband Integrated Television Tuner; and U.S. patent application Ser. No. 09/572,393 filed May 16, 2000 and entitled Broadband Integrated Tuner.

### TECHNICAL FIELD

The invention generally relates to gain control circuits and more particularly to automatic gain control mechanisms and methods for use with or forming a part of various electronic apparatus including signal amplifiers such as used in television tuners.

### BACKGROUND OF THE INVENTION

Many electronic applications use signal amplifiers to increase the level of a signal to some desired level. Often the amplifier must accommodate a wide range of input signal levels while maintaining some desired output signal level. The function of maintaining the output signal level constant may be performed by an automatic gain control (AGC) circuit that is part of or operates in cooperation with an amplifier circuit and/or signal attenuator circuit. For example, a television tuner or other radio receiver may have in initial radio frequency (RF) amplifier stage receiving a modulated RF signal such as an off-the-air or cable television signal.

The input signal applied to an input of the RF amplifier stage can have a signal level that varies over a wide range of values. For example, a television receiver/demodulator may be required to operate with an RF input signal level in the range of 0.2 mV to 30 mV or −14 dBmV (20 log 0.2 wherein 0 dBmV=1.0 mV) to +29 dBmV (20 log 30) with a preferred range of 2.0 mV to 10 mV (+6 dBmV to +20 dBmV). An RF amplifier stage might provide, for example, 15 dB of amplification so that the signal provided to a subsequent stage might be somewhere in the range of 0 dBmV to +45 dBmV. An AGC circuit may be used to confine the signal level to some smaller range to better accommodate the input signal level requirement of the next stage, e.g. a filter, subsequent amplifier, mixer used to down-convert the signal to an intermediate frequency (IF), etc. However, if the input signal is provided to an amplifier stage is already sufficient, it may be necessary to attenuate the signal to avoid overdriving or overloading the amplifier.

For example, an RF amplifier is typically part of an input circuit (e.g., an RF input stage) of a television tuner circuit that may be formed as part of an integrated circuit. The RF signal may be supplied by an “off-the-air” antenna system, a cable television system (CATV), satellite television system, or other source. Each of these sources can and often do provide signal levels that vary significantly and must be accommodated by a television tuner circuit. For very low level signals it is desirable to use a very low noise RF amplifier that does not substantially degrade (e.g., distort) the input signal. However, as the signal level increases the RF amplifier can overload and cause distortion. Thus, there are these two boundaries: (i) a minimum signal level wherein a substantial level of signal amplification results in the addition of noise while (ii) maximum or high signal levels may overload the amplifier and cause distortion.

Often, the approach to the problem of handling a wide range of signal input levels is to simply design input amplifiers to be very low noise and have very good distortion specifications such that the circuit can accomodate a wide range of signal levels without introducing an excessive level of distortion to the output signal supplied to a next stage. Thus, the amplifier has both a very high gain capability and very low noise. In this case, as the signal level increases the amplifier is highly linear while exhibiting low distortion to avoid signal degradation. Unfortunately, the wide range of input signal levels that are to be accommodated requires significant power consumption to maintain linearity over the full range of input signal levels and results in significant heat generation by the amplifier.

To maintain the signal level of the amplified signal at some desired level, such amplifiers may include a variable gain functionality that may be part of an automatic gain control (AGC) circuit. To satisfy noise and distortion requirements, these amplifiers may operate at some maximum gain for a certain period of time until distortion starts to become a problem at which time gain is reduced such that noise and distortion contributions become essentially fixed. As gain is reduced, the output signal level remains constant. That is, as gain is reduced in response to an increasing input signal level, the effective signal-to-noise ratio remains constant as does noise and signal distortion.

To accommodate typical input signal levels and maintain a desired output level, an amplifier may be designed so that a certain amount of noise is added by the amplifier up to a certain signal level. The signal level to which the noise is added determines the power level required by the amplifier to maintain a desired linearity so as to avoid excessive signal distortion. Thus, the input signal level to be amplified is an important design factor, with definition of acceptable distortion levels providing a breakpoint defining maximum gain. Once the input signal reaches that point it is possible to start reducing amplifier gain to maintain distortion levels constant. As the signal level continues to increase the amplifier begins to attenuate the input signal level so that the signal-to-noise and signal-to-distortion values remain constant. At some point an associated attenuator reduces the signal level from the amplifier by the same amount of gain as provided by the amplifier. In this case higher input signal levels result in the amplifier not really doing anything except operating to introduce noise and/or distortion into the signal, i.e., the amplifier is increasing signal level but that signal level is immediately reduced by an attenuator circuit back down to its original level.

Accordingly, an object of the invention is to provide a device, system using such device, and method of accommodating a wide range of input signals levels while minimizing power consumption and/or minimizing the introduction of noise and distortion.

### BRIEF SUMMARY OF THE INVENTION

The present invention is directed to devices, systems and methods that accommodate a wide range of input signal levels while providing desired signal amplification within predetermined distortion limits while minimizing power consumption, noise, and/or distortion. According to one aspect of the invention, a level control circuit detects the level of a signal by sampling at the output of active circuit such as a signal amplification stage. If the signal level is sufficient such that the processing by the active circuit (e.g., signal amplification) is not necessary, the level control circuit bypasses the active circuit and may interrupt power to the circuit to reduce power consumption and heat generation. The level control circuit may further function to adjust the gain of the active circuit, either directly or using an attenuation circuit. A sampling circuit or signal level detector may provide a control signal to dynamically adjust gain parameters (including bypass of unnecessary amplification stages) to implement an automatic gain control (AGC) function. Gain control and amplification circuits may be combined and used in various devices and applications including in, but not limited to, one or more radio frequency (RF), intermediate frequency (IF), baseband video and/or audio, or other stages of a television tuner and/or demodulator.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWING

For a more complete understanding of the present invention, reference is now made to the following descriptions taken in conjunction with the accompanying drawing, in which:

FIG. 1 is a block diagram of a level control circuit connected to an amplifier and associated attenuator circuit to provide an automatic gain control (AGC) function according to a first embodiment;

FIG. 2 is a block diagram of a level control circuit connected to an amplifier and associated attenuator circuit to provide an automatic gain control function according to a second embodiment;

FIG. 3 is a graph depicting level control circuit operation for various input signal level conditions and corresponding output signal levels; and

FIG. 4 is a block diagram of a television tuner incorporating AGC functionality and circuitry according to an embodiment of the present invention.

### DETAILED DESCRIPTION OF THE INVENTION

The present invention includes embodiments in which a level control circuit is responsive to some parameter of an input signal, e.g., signal level, to selectively bypass some active circuit (e.g., amplifier stage) rendered unnecessary in view of the detected condition of the input signal, e.g., a signal level satisfying some threshold criteria. The condition may be static or dynamically set and/or adjusted. According to an embodiment of the invention, the control circuit may further reduce or interrupt power to or disable operation of the active circuit to minimize power consumption. For example, in the case of an amplifier circuit that may be part of a radio frequency (RF) input stage of a receiver or tuner, upon detecting some threshold input signal level, the amplifier circuit is bypassed, i.e., taken out of the signal feed path and power to the circuit removed (or reduced if, for example, to provide for rapid circuit reinsertion if desired) thereby removing noise and distortion otherwise introduced into the signal by the amplifier. The signal is routed around the amplifier circuit to a subsequent circuit, stage or device such as a signal attenuator circuit. Bypassing unnecessary amplification circuits provides a particular advantage in “table case” situations in which circuit stage design must accommodate a variable signal level including some very high signal levels since, in general, the signal levels tend to be at a high end of the range.

Embodiments of the invention take into consideration the amount of power a particular circuit or stage requires. At some point, as a level of an applied signal continues to increase, there is a value at which the gain of the amplifier is reduced to one or unity gain. Similarly, an amplifier and attenuator combination providing automatic gain control operation may be controlled to a point where the amplifier gain equals the attenuation provided by the attenuator. At either such point there is no real use for the amplifier. Instead, the amplifier merely adds noise and distortion and consumes more power causing more heat to be generated. When the gain provided by an amplifier essentially becomes 1, the amplifier is removed from the circuit and bypassed according to embodiments of the invention.

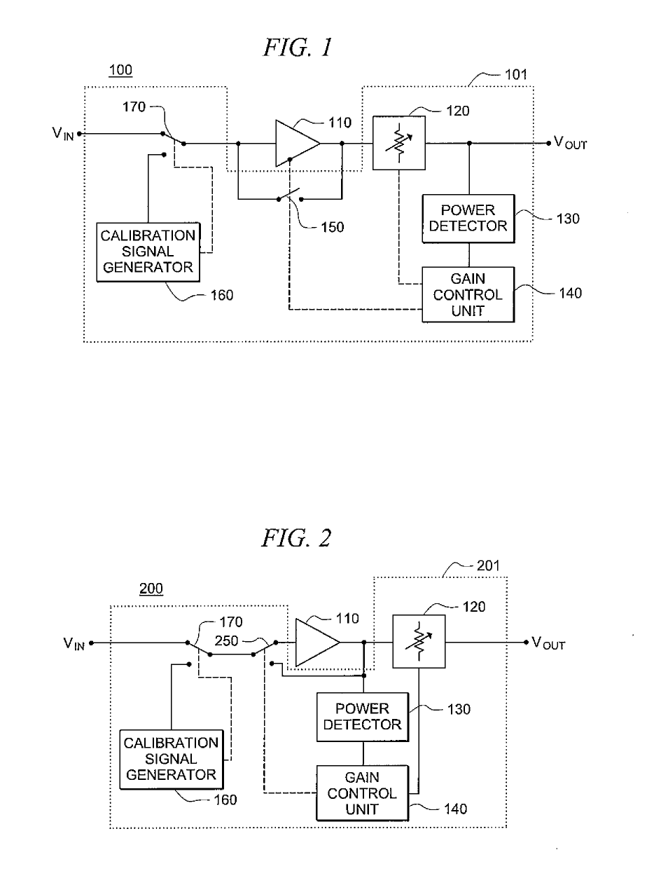

FIG. 1 is a block diagram of an RF amplifier stage 100 incorporating circuitry according to an embodiment of the invention including a gain control circuit or Level controller 101 in combination with an active circuit in the form of amplifier 110. Various components of RF amplifier stage 100 may be disposed in common integrated circuit substrate, perhaps also having disposed therein additional signal processing circuitry such as one or more mixers of an integrated circuit tuner. For example, according to one embodiment, amplifier 110, attenuation circuit 120, and power detection 130 are disposed in a same integrated circuit. Embodiments further comprise such control unit 140 and/or calibration signal generation 160 in the foregoing integrated circuit. Of course, there is no limitation that such integrated circuit configurations must be implemented according to embodiments of the invention. Accordingly, some of the foregoing functional blocks, or portions thereof, may be disposed “off chip”. Likewise, embodiments of the present invention may be comprised of discrete components. However, the power saving, noise, and distortion improvements provided by embodiments of the present invention are particularly advantageous with respect to environments wherein integrated circuit solutions are desired (e.g., portable, low power, small, etc. RF electronic devices).

An input signal, such as one that might be provided by a cable television (CATV) system, may be applied amplifier 110. An amplified output from amplifier 110 is provided to variable attenuator circuit 120. Thus, the output from variable attenuator circuit 120 represents the output voltage of RF amplifier stage 100 with gain control. Level controller 101 further includes a power detector 130 connected to the output of variable attenuator circuit 120 for measuring the signal level coming out of amplifier 110 and variable attenuator circuit 120. Gain control unit 140 processes inputs from data stored in connection with related circuitry, e.g., a tuner incorporating the system, including the desired signal voltage or power level required at the output of the RF amplifier stage, for example some level at which distortion starts to become a problem so that gain provided by the stage is reduced. For example, as the voltage of the output signal Vₒᵤₜ from variable attenuator circuit 120 equals or exceeds some threshold value, gain control unit 140 responds to reduce the signal levels to avoid causing signal distortion by subsequent stages due to excessive signal levels. This is effectuated by providing an appropriate control signal to variable attenuator circuit 120 to reduce Vₒᵤₜ to achieve some desired, preferably constant voltage level. Thus, power detector 130 in combination with gain control unit 140 functions to provide a desired constant signal output level with levels detected below the desired level being amplified by amplifier 110 operating at maximum gain.

Bypass circuit 150 may be implemented comprising a switch to provide a path around amplifier 110 in response to Vᵢₙ equal to or greater than the desired Vₒᵤₜ, e.g., the RF amplifier stage need only provide a gain of unity or “1”. In this case, amplification by amplifier 110 is unnecessary, resulting in the amplifier unnecessarily consuming power, generating heat and introducing noise and/or signal distortion. Therefore, at an appropriate threshold level or transition point P, bypass circuit 150 operates to bypass amplifier 110 and, at the same time, attenuator circuit 120 is reset to a zero (or no attenuation level) or otherwise as necessary to provide a desired signal level. As detailed below, the threshold level or transition point P may correspond to a value different (e.g. greater) than that of desired Vₒᵤₜ value. That is, upon detecting a level greater than some desired Vₒᵤₜ, attenuator circuit 120 starts to attenuate to maintain the desired Vₒᵤₜ. As level of the input signal Vin continues to increase to threshold value P (for example some value such that inherent losses through the stage are taken into account), bypass circuit 150 is activated to bypass and deenergize amplifier 110 and set attenuator circuit 120 to no attenuation so that the input and the output are essentially the same. As the input level further increases, attenuator circuit 120 again lowers the signal level to maintain the desired Vₒᵤₜ value.

In the configuration shown in FIG. 1, power detector 130 samples signal levels at the output of attenuator circuit 120. Thus, to determine the level of input signal Vᵢₙ, the level of amplification provided by gain G of amplifier 110 (if not bypassed) and attenuation A provided by attenuator circuit 120 is taken into consideration. That is:

$${V}_{i n} = {V}_{out} ( \frac{{A}_{120} + {A}_{parasitic}}{G} )$$

where:

Vᵢₙ=signal level applied to the stage;

Vₒᵤₜ=signal level sampled at the output of attenuator circuit 120;

A₁₂₀=attenuation level provided by attenuator circuit 120; and

A_{parasitic}=attenuation due to other causes including losses through bypass circuit 150.

Note that other sampling points may be used although, typically, levels are measured at or after the output of amplifier 110. This is generally the case since signal parameters at the input node are relatively sensitive and, particularly during periods of low signal levels, noise and/or distortion may be easily introduced. In preferred embodiments that sample signal levels at the output of amplifier 110 it may be useful to know the values of the various parameters affecting the signal level as, for example, given or represented by the equation above. These parameters include, but are not limited to, the gain G of amplifier 110, attenuation level A₁₂₀ introduced by attenuator circuit 120 in response to various control signals, parasitic attenuation A_{parasitic} due to other causes including losses through bypass circuit 150, etc. Depending on circuit performance requirements, process variations during circuit manufacturing and/or due to other causes may result in variations in these values to a degree that the relationship between input and output levels may be uncertain without performing actual measurements. It is based on these values that appropriate thresholds can be determined and instituted for bypassing amplifier 110 and controlling attenuator circuit 120 to obtain a desired output signal level. The values may also be useful to satisfy requirements for instantaneous gain steps. That is, if circuit gain changes instantaneously or too rapidly, system problems may result. To address these issues, it is desirable to know precise values for gain and attenuation.

To determine gain and attenuation values for the various components, a source of a standard or known signal level, such as provided by calibration signal generator 160, maybe provided. Calibration signal generator may be provided on the same integrated circuit chip as the other components of RF amplifier stage 100 or as an external device. Using such a standard it is possible to measure signal levels (e.g., voltage, power, etc) output by amplifier 110 and attenuated by attenuator circuit 120 when set to a particular attenuation level and/or over a range of attenuation levels. Circuit 170 (e.g., switching circuitry) is used to selectively apply either (i) the standard signal output from calibration signal generator 160 to the input of amplifier 110 for calibration and testing purposes or, in an operational mode (ii) an input signal to be amplified and/or otherwise processed (e.g., a television RF signal).

Once the various gain and attenuation values are determined, gain control unit 140 may be programmed or otherwise configured to selectively bypass and power-down amplifier 110. As previously mentioned, although embodiments of the invention may include means for interrupting power to at least the active circuitry of amplifier 110 (represented by the dashed line from gain control unit 140 to amplifier 110 in FIG. 1), alternative means of conserving power consistent with circuit operation may be employed. For example, an appropriate bias voltage may be supplied to place power consuming elements of amplifier 110 in a standby or low power consumption mode or state. This may be useful to provide for rapid reactivation of amplifier functionality in response to a reduced input signal level.

Further, although the embodiment of FIG. 1 includes amplifier 110 in combination with attenuator circuit 120 to provide level adjustment and control of an output signal, other configuration may be used. For example, a variable gain amplifier may be used so as to eliminate the need for a separate attenuation capability.

FIG. 2 is a block diagram of an alternative configuration of an RF amplifier stage 200 to that shown in FIG. 1. In FIG. 2, bypass circuit 250 operates to selectively apply an input signal to either the input terminal or output terminal of amplifier 110. Thus, when bypassed, the input signal is not simultaneously supplied to both the input and output of the amplifier. Note also that other bypassing and switching configurations may be employed. For example, it may be desirable in some configurations to ground the input of amplifier 110 to avoid generation of extraneous noise at its output if the amplifier is not completely disabled by interruption of power to its active circuitry. Another difference between embodiments is in that level controller 201 connects power detector 130 directly to the output of amplifier 110 rather than to the output of attenuator circuit 120. In either configuration, a detector output from power detector 130 is supplied to gain control unit 140. Gain control unit 140 responds to the detector output to both selectively bypass around amplifier 110, control power to the amplifier, and to control attenuator circuit 120 so as to provide a desired signal output level, e.g., implements an AGC functionality.

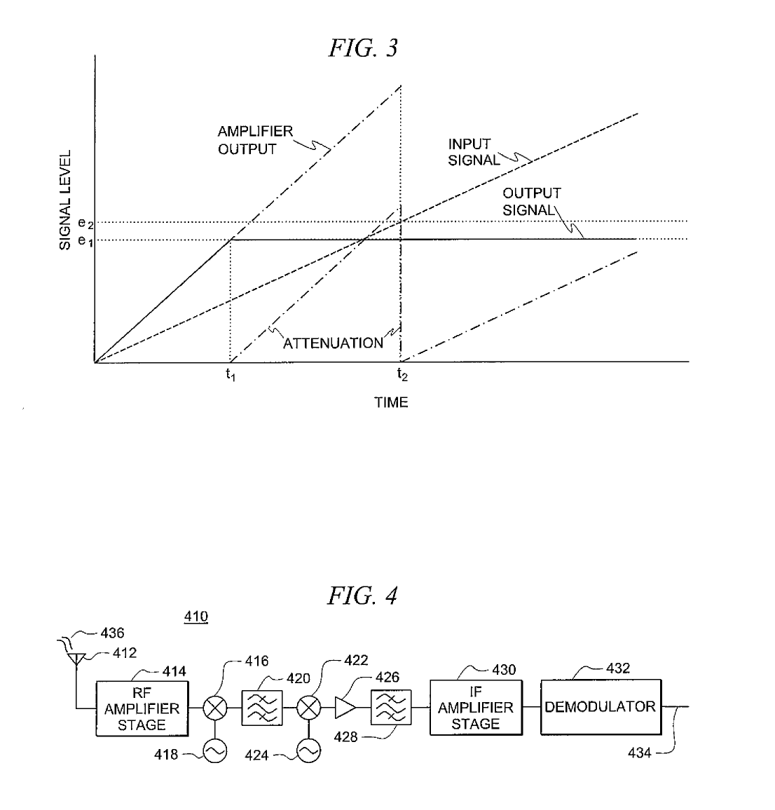

FIG. 3 is a graph depicting level control circuit operation for various input signal level conditions and corresponding output signal levels. As depicted, an ideal amplifier may have a linear input to output transform labeled in FIG. 3 as “amplifier output.” At some input signal level l₁ at time t₁ attenuator circuit 120 starts to attenuate the level of the signal from amplifier 110 by an amount shown by the line labeled “attenuation” so as to achieve a constant output signal level labeled as “output signal” between times t₁ and t₂. At time t₂ the input signal reaches some threshold value level l₂ such that amplifier is operating at or below unity gain, i.e., is no longer needed to provide a suitable signal level. Thus, at time t₂ gain control unit 140 operates to bypass and power-off amplifier 110 and reduce the attenuation of the signal effectuated by attenuator circuit 120 to maintain a constant output signal level. In those configurations wherein the bypass operation itself reduces signal strength, bypass of amplifier 110 may be in response to a threshold input signal level that is greater than the desired output signal level to account for circuit, switching and parasitic losses.

Bypass circuitry according to embodiments of the present invention may be used in various applications and environments including, but not limited to, the amplifier and/or AGC circuits illustrated. Further, while particularly applicable to RF systems wherein signal levels are notoriously variable so that amplification requirement vary significantly, other applications are possible including, for example, audio preamplification stages, etc. In connection with the illustrated RF environment, amplifier stage configurations according to embodiments of the invention may be used, for example, as part of a television tuner. Thus, referring to FIG. 4, a television receiver, some or all of which may be disposed in a game integrated circuit substrate, may include a tuner 410 having an input device 412 coupled to an RF amplifier stage 414 for supplying an RF signal such as, but not limited to, an off-the-air or cable television signal. Although FIG. 4 is illustrated and detailed with respect to a particular dual conversion tuner architecture for tuner 410, it should be understood that any suitable single, dual, or direct conversion tuner architecture may be used without departing from the scope of this disclosure. Therefore, while a particular example of tuner 410 is illustrated and described herein, other architectures for tuner 410 are applicable.

Referring to FIG. 4, an RF output of RF amplifier stage 414 is connected to first mixer 416 for down-converting the RF signal from RF amplifier stage 414 to a first intermediate frequency (1^{st} IF). RF amplifier stage 414 may be implemented as detailed above in connection with FIG. 1 of the drawings or otherwise consistent with the various embodiments of the present invention. For example, although the circuit may be implemented using an attenuator, implementations including a controllable gain amplifier circuit may he provided.

First mixer 416 is coupled to RF amplifier stage 414 and a first local oscillator 418. First filter 420 is coupled to first mixer 416 and second mixer 422, which is further coupled to second local oscillator 424. First IF amplifier 426, such as a low noise amplifier (LNA), couples second mixer 422 to second filter 428. Tuner 410 may further comprise second IF amplifier stage 430 coupled to second filter 428 which supplies a filtered IF signal to second IF amplifier 430. The filtered and amplified IF signal from second IF amplifier 430 is coupled to demodulator 432 for providing one or more baseband output signals, e.g., video and/or audio signals derived from information modulated on the RF and IF signals.

Input device 412 may comprise a terrestrial antenna, a cable input, a satellite dish, or any other suitable device for receiving a broadband signal 436 from a variety of sources. Signal 436 may comprise video and audio data carried on analog or digital signals, such as RF signals over a frequency range. In this regard, signal 436 comprises a modulated signal. In one embodiment, signal 436 may comprise signals in the television band.

First mixer 416 may be any suitable device that multiplies an RF signal received from RF amplifier circuit 414 with a local oscillator (LO) signal received from first local oscillator 418 to generate an IF signal. Local oscillator 418 may comprise any suitable device that generates a local oscillator signal at a selected frequency.

In one embodiment, the local oscillator frequency associated with local oscillator 418 is selected so that mixer 416 performs an up-conversion of the RF signal received from RE amplifier circuit 414.

Filter 420 may comprise any suitable number and combination of frequency selective components that may be used in tuner 410. In one embodiment, filter 420 comprises a band pass filter that provides coarse channel selection of signals 436 in tuner 410.

As a matter of design choice, filter 420 may be constructed on the same integrated circuit substrate as mixers 416 and 422, or filter 420 may be a discrete off-chip device.

Filter 420 selects a band of channels or even a single channel from the signals 436 in the IF signal received from mixer 416.

Following filter 420, mixer 422 mixes the first IF signal with a second local oscillator signal from local oscillator 424 to generate a second IF signal.

In one embodiment, mixer 422 performs a down conversion of the IF signal to a particular frequency. The second IF signal then passes through filter 428 which limits the bandwidth of the signal to a single channel by attenuating unwanted adjacent channels.

In one embodiment, filter 428 comprises a surface acoustic wave (SAW) filter. The output of filter 428 is input to second IF amplifier stage 430 which may also be implemented to provide gain control functionality (e.g., include AGC) in accordance with various embodiments of the present invention.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A level controller for use with an amplifier, said level controller comprising:
a detector responsive to a signal level for generating a detector output signal; and
a bypass circuit responsive to said detector output signal for bypassing a signal around an active portion of the amplifier.

2. The level controller according to claim 1 wherein said detector is connected to an output of said amplifier for detecting said signal level.

3. The level controller according to claim 1 further comprising:
a gain control circuit connected to said power detector for receiving said detector output signal and, in response to said output signal indicating a level of said signal exceeding a threshold value, supplying a bypass control signal to said bypass circuit, said bypass circuit responsive to said bypass control signal for bypassing the signal around the active portion of the amplifier.

4. The level controller according to claim 3 wherein said gain control circuit further comprises a power controller for interrupting operation of the amplifier in response to said output signal indicating a level of said signal exceeding said threshold value.

5. The level controller according to claim 3 wherein said gain control circuit further controls a level of an output signal from the amplifier.

6. The level controller according to claim 3 wherein said gain control circuit is connected to and provides a gain control signal to the amplifier for varying an amplification level of the amplifier.

7. The level controller according to claim 3 further comprising an attenuator circuit connected to an output of said amplifier and receiving a gain control signal from said controller for controlling an attenuation of an output signal from said amplifier.

8. The level controller according to claim 1 further comprising:
a calibration signal generator selectively connected to an input of the amplifier for providing a standard level input signal thereto.

9. An amplifier comprising:
an amplifier circuit having
(i) an input connected to receive an input signal,
(ii) an active portion receiving and amplifying said input signal to supply an amplified output signal, and
(iii) an output supplying said output signal;
a gain control circuit responsive to a level of said output signal for supplying a bypass control signal; and
a bypass circuit responsive to said bypass control signal for bypassing said input signal around said active portion of said amplifier circuit and supplying said input signal as said output signal.

10. The amplifier according to claim 9 wherein said gain control circuit further supplies a gain control signal, said amplifier circuit responsive to said gain control signal for controlling an amplification level of said amplifier circuit.

11. The amplifier according to claim 10 wherein said amplifier circuit includes a variable attenuator circuit responsive to said gain control signal for controlling a level of said output signal.

12. The amplifier according to claim 10 wherein said amplifier circuit is responsive to said gain control signal for controlling a level of amplification of said active portion of said amplifier circuit.

13. A tuner comprising:
a radio frequency (RF) input stage;
an RF converter stage connected to said RF input stage and receiving an RF signal therefrom to provide an intermediate frequency (IF) signal;
an IF amplifier stage including
(i) an amplifier circuit having active portion receiving and amplifying said IF signal to provide an output IF signal,
(ii) a gain control circuit responsive to a level of said IF signal for supplying a bypass control signal, and
(iii) a bypass circuit responsive to said bypass control signal for bypassing said IF signal around said active circuitry of said amplifier circuit and selectively supplying said IF signal from said RF converter as said output IF signal; and
a signal detector demodulating said output IF signal to provide a demodulated output signal.

14. The tuner according to claim 13 wherein said gain control circuit further comprises a power controller for interrupting operation of the amplifier circuit in response to said IF signal from said RF converter attaining a level exceeding a threshold value.

15. The tuner according to claim 13 wherein said gain control circuit further controls a level of amplification provided by said amplifier circuit.

16. The tuner according to claim 13 wherein said gain control circuit is connected to and provides a gain control signal to said amplifier circuit for varying an amplification level of said active portion of the amplifier circuit.

17. The tuner according to claim 13 wherein said IF amplifier further comprising an attenuator circuit connected to an output of said amplifier circuit and receiving a gain control signal from said controller for controlling an attenuation of said output IF signal from said amplifier circuit.

18. A method of controlling amplification of an input signal by an amplifier comprising the steps of:
generating a detector output signal in response to a level of said input signal; and
selectively bypassing said input signal around the amplifier in response to said detector output signal indicating a level of said input signal exceeding a threshold value.

19. The method according to claim 18 further comprising a step of interrupting operation of the amplifier in response to said detector output signal indicating a level of said input signal exceeding said threshold value.

20. The method according to claim 18 further comprising a step of controlling a gain of the amplifier.

21. The method according to claim 18 further comprising a step of attenuating an output from said amplifier in response to a level of said input signal.

22. The method according to claim 18 further comprising a step of providing a calibration signal to said amplifier and determining a gain setting of said amplifier such that amplification of said input signal is not required.

23. A method of processing a signal comprising the steps of:
converting a radio frequency (RF) signal to an intermediate frequency (IF) signal;
detecting a level of said IF signal;
selectively amplifying said IF signal when below a threshold level and bypassing an amplification stage when above the threshold level; and
demodulating said IF signal to provide a demodulated output signal.

24. The method according to claim 23 further comprising a step of interrupting operation of the amplifier stage in response to said IF signal level exceeding said threshold level.

25. The method according to claim 23 further comprising a step of controlling a gain of said amplification stage in response to said level of said IF signal.
